(19) United States
(12) Patent Application Publication
(10) Pub. No.: US 2013/0063906 A1
(43) Pub. Date: Mar. 14, 2013

(54) CIRCUIT BOARD ASSEMBLY AND ELECTRONIC DEVICE WITH CIRCUIT BOARD

(71) Applicants: Yong-Nian CHEN, Wuhan City (CN); Li-Fu XU, Wuhan City (CN); Yue-Yong LI, Wuhan City (CN); Jin-Wen OU, Wuhan City (CN)

(72) Inventors: Yong-Nian CHEN, Wuhan City (CN); Li-Fu XU, Wuhan City (CN); Yue-Yong LI, Wuhan City (CN); Jin-Wen OU, Wuhan City (CN)

(73) Assignees: HON HAI PRECISION INDUSTRY CO., LTD., Tu-Cheng (TW); HONG FU JIN PRECISION INDUSTRY (WuHan) CO., LTD., Wuhan City (CN)

(21) Appl. No.: 13/474,804

(22) Filed: May 18, 2012

(30) Foreign Application Priority Data
Sep. 9, 2011 (CN) 201110267009.5

(51) Int. Cl. H05K 7/00; H05K 1/02

(52) U.S. Cl. 361/752; 174/268

(57) ABSTRACT

An electronic device includes a chassis, a circuit board and the resilient piece. The chassis includes a bottom panel. The circuit board has a ground plane. The resilient piece includes a soldering portion and a resisting portion. The soldering portion is in electrical connection with the ground plane, and the resisting piece abuts the bottom panel to prevent the electromagnetic interference (EMI) from the circuit board.

### BACKGROUND

1. Technical Field

The present disclosure relates to electronic devices, and particularly to an electronic device with a circuit board.

2. Description of Related Art

In a computer or a sever, electromagnetic interference (EMI, also called radio frequency interference (RFI)) is a disturbance that affects a circuit board due to either electromagnetic conduction or electromagnetic radiation emitted from an external source. The disturbance may interrupt, obstruct, degrade or limit the effective performance of the circuit board. Usually, an extra filter waver circuit is added on the circuit board, or a plurality of holes connected with ground are defined in the circuit board, to dispel the EMI. However, the plurality of holes may influence a layout of the circuit board, and the extra filter waver circuit may increase cost.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device, the electronic device comprising a chassis, a circuit board and a resilient piece.

FIG. 2 is a partly, assembled view of the circuit board and the resilient piece of FIG. 1.

FIG. 3 is an isometric view of the resilient piece of FIG. 1.

FIG. 4 is an assembled view of the electronic device of FIG. 1.

FIG. 5 is a cross-sectional view of the electronic device of FIG. 4, taken along the line V-V.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

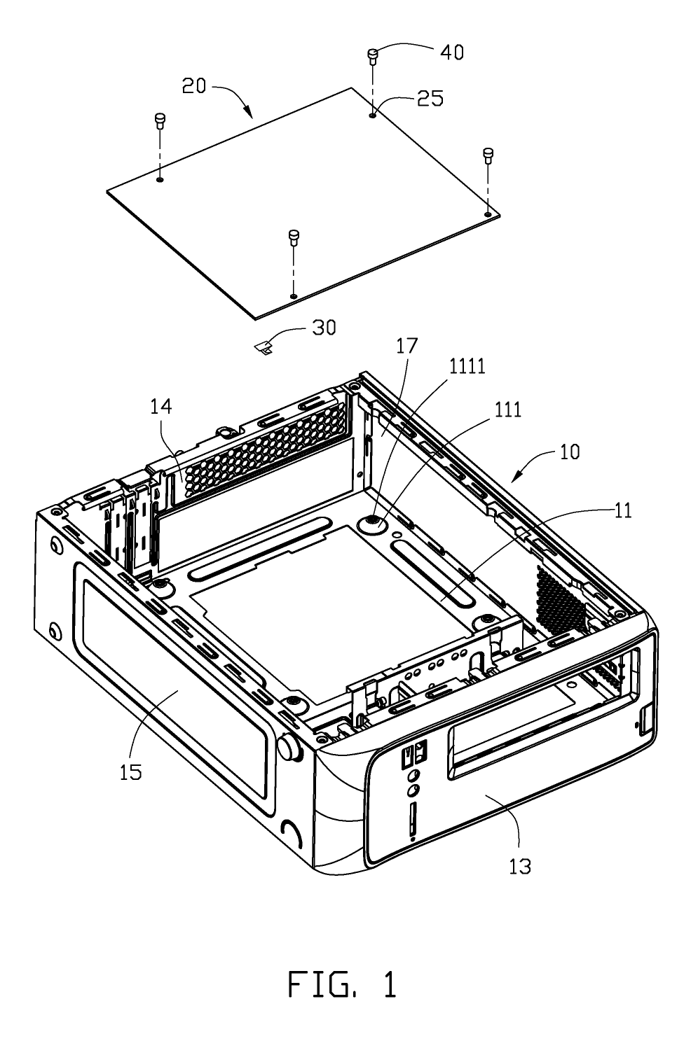

FIG. 1, is an embodiment of an electronic device including a chassis 10, a circuit board 20 and a resilient piece 30.

The chassis 10 includes a bottom panel 11, a front panel 13, a rear panel 14, a first side panel 15 and a second side panel 17. In one embodiment, the front panel 13 is substantially parallel to the rear panel 14 and perpendicularly connected to the bottom panel 11, the first side panel 15 is substantially parallel to the second side panel 17 and perpendicularly connected to the bottom panel 11. Four protrusions 111 are located on the bottom panel 11. In one embodiment, the four protrusions 111 are arranged at four corners of a rectangular area. Each of the four protrusions 111 defines a threaded hole 1111.

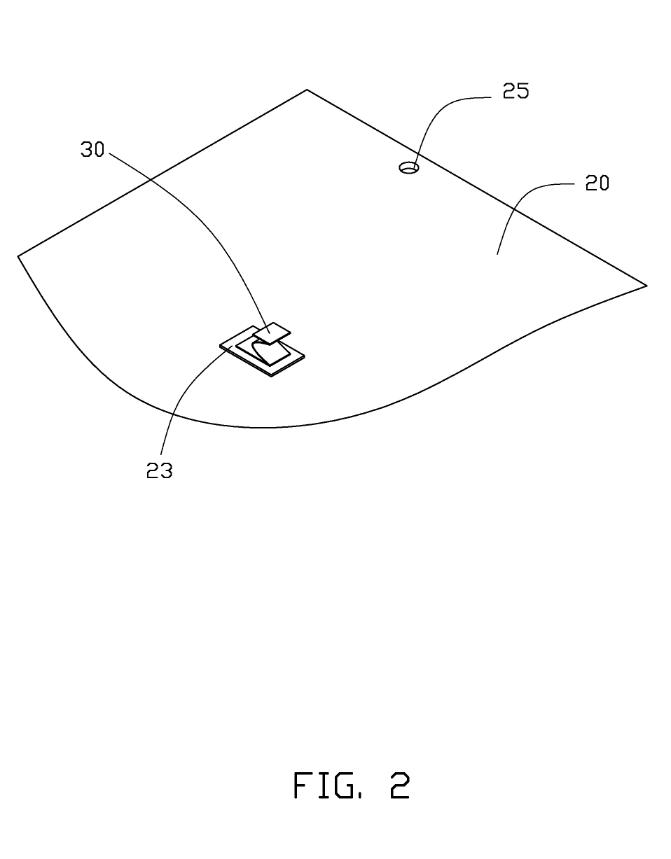

FIG. 2, shows the circuit board 20 has a ground plane (not shown), a conductive piece 23 is electrically connected to the ground plane. In one embodiment, the conductive piece 23 is made of gold. The circuit board 20 defines four securing holes 25. In one embodiment, the four securing holes 25 are arranged at four corners of the circuit board 20.

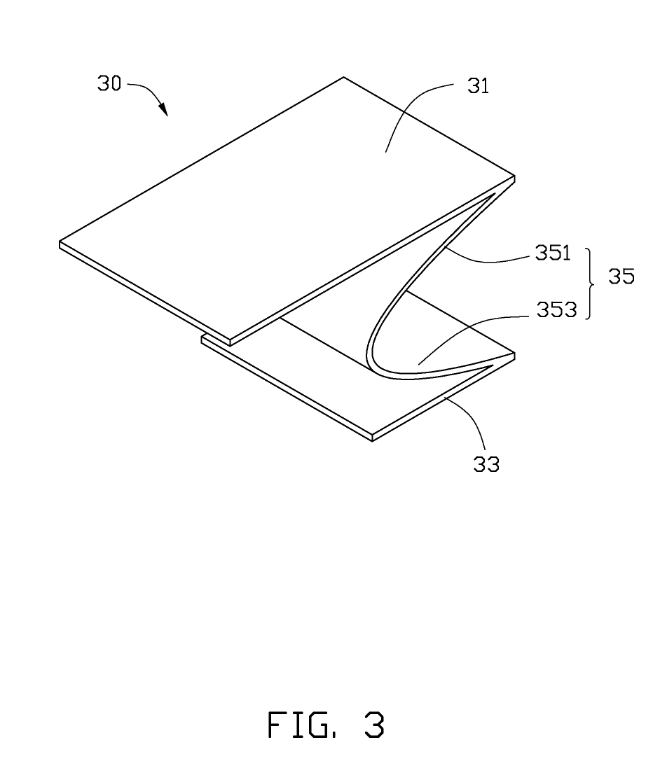

FIG. 3, shows the resilient piece 30 includes a soldering portion 31, a resisting portion 33 and a connecting portion 35 connected to the soldering portion 31 and the resisting portion 33. In one embodiment, the soldering portion 31 is substantially parallel to the resisting portion 33, the connecting portion 35 is located between the soldering portion 31 and the resisting portion 33. The connecting portion 35 includes a first resilient portion 351 and a second resilient portion 353. The first resilient portion 351 extends inwards from a distal end of the soldering portion 31. In one embodiment, a first acute angle is defined between the first resilient portion 351 and the soldering portion 31. The second resilient portion 353 is bent downwards from a distal end of the first resilient portion 351. In one embodiment, the connecting portion 35 is substantially arc-shaped, and a second acute angle is defined between the first resilient portion 351 and the second resilient portion 353. A free end of the second resilient portion 353 is connected to a distal end of the second resilient portion 353. In one embodiment, a third acute angle is defined between the second resilient portion 353 and the resisting portion 33.

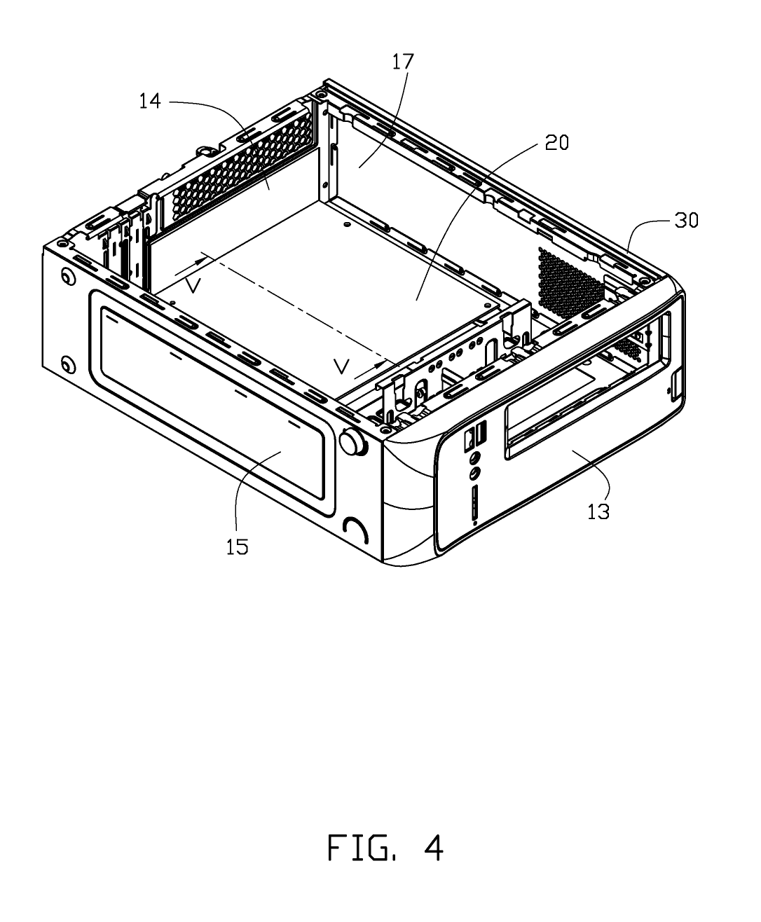

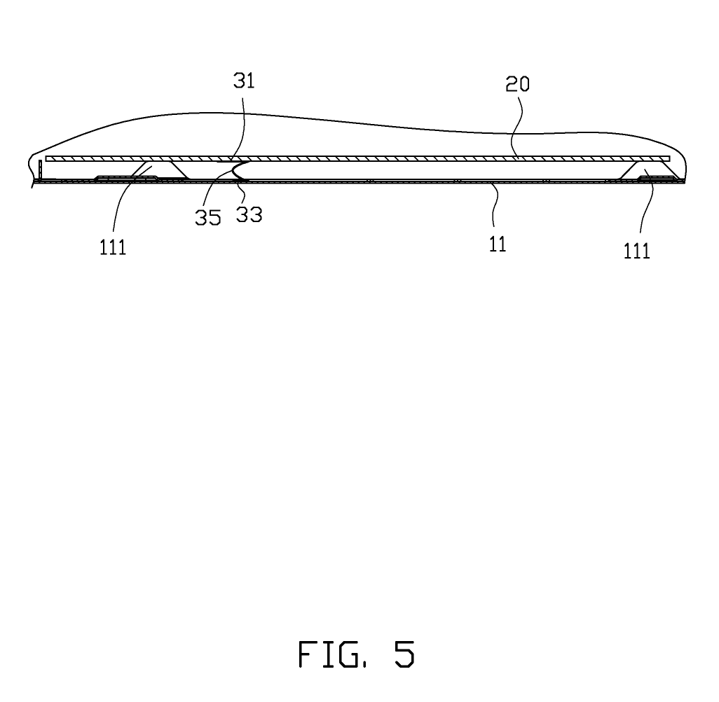

FIG. 2, shows the resilient piece 30 soldered to the conductive piece 23 by the soldering portion 31. FIG. 4-5, show in assembly of the circuit board 20, the circuit board 20 is placed on the four protrusions 111. Each of the four securing holes 25 is aligned with each of the four threaded holes 1111, and each of four fixing members 40 is inserted into each of the four securing holes 25 and corresponding one of the threaded holes 1111. Thus, the circuit board 20 is installed on the chassis 10. The resisting piece 13 abuts the bottom panel 11 to prevent the electromagnetic interference (EMI).

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device comprising:
a chassis, the chassis comprising a bottom panel;
a circuit board, the circuit board defining a ground plane; and
a resilient piece, the resilient piece comprising a soldering portion and a resisting portion, wherein the soldering portion is in electrical connection with the ground plane; and the resisting portion abuts on the bottom panel, the resisting piece being configured to shield electromagnetic interference (EMI) from the circuit board.

2. The electronic device of claim 1, wherein a conductive piece is located on the circuit board and electrically connected to the ground plane.

3. The electronic device of claim 2, wherein the conductive piece is made of gold.

4. The electronic device of claim 2, wherein the soldering portion is secured to the conductive piece.

5. The electronic device of claim 1, wherein the resilient piece further comprises a connecting portion connected to the soldering portion and the resisting portion, and the connecting portion is located between the soldering portion and the resisting portion.

6. The electronic device of claim 5, wherein the connecting portion comprises a first resilient portion extending from a distal end of the soldering portion, and a first acute angle is defined between the first resilient portion and the soldering portion.

7. The electronic device of claim 6, wherein the connecting portion further comprises a second resilient portion bending from a distal end of the first resilient portion, and a second acute angle is defined between the second resilient portion and the first resilient portion.

8. The electronic device of claim 7, wherein a free end of the second resilient portion is connected to a distal end of the resisting portion, and a third acute angle is defined between the second resilient portion and the resisting portion.

9. The electronic device of claim 6, wherein the connecting portion is substantially arc-shaped.

10. The electronic device of claim 1, wherein the soldering portion is substantially parallel to the resisting portion.

11. A circuit board assembly comprising:
a circuit board, the circuit board defining a ground plane; and
a resilient piece, the resilient piece comprising a soldering portion and a resisting portion, wherein the soldering portion is electrical connection with the ground plane; and the resisting portion is configured to abut an electronic enclosure and to shield electromagnetic interference (EMI) from the circuit board.

12. The circuit board assembly of claim 11, wherein a conductive piece is located on the circuit board and electrical connection with the ground plane.

13. The circuit board assembly of claim 12, wherein the conductive piece is made of gold.

14. The circuit board assembly of claim 12, wherein the soldering portion is secured to the conductive piece.

15. The circuit board assembly of claim 11, wherein the resilient piece further comprises a connecting portion connected to the soldering portion and the resisting portion, and the connecting portion is located between the soldering portion and the resisting portion.

16. The circuit board assembly of claim 15, wherein the connecting portion comprises a first resilient portion extending from a distal end of the soldering portion, and a first acute angle is defined between the first resilient portion and the soldering portion.

17. The circuit board assembly of claim 16, wherein the connecting portion further comprises a second resilient portion bending from a distal end of the first resilient portion, and a second acute angle is defined between the second resilient portion and the first resilient portion.

18. The circuit board assembly of claim 17, wherein a free end of the second resilient portion is connected to a distal end of the resisting portion, and a third acute angle is defined between the second resilient portion and the resisting portion.

19. The circuit board assembly of claim 16, wherein the connecting portion is substantially arc-shaped.

20. The circuit board assembly of claim 11, wherein the soldering portion is substantially parallel to the resisting portion.
